(19) United States
(12) Patent Application Publication
(10) Pub. No.: US 2016/0172522 A1
(43) Pub. Date: Jun. 16, 2016

(54) MULTI-JUNCTION SOLAR CELL AND METHOD FOR MANUFACTURING THEREOF

(71) Applicants: NATIONAL UNIVERSITY CORPORATION TOKYO UNIVERSITY OF AGRICULTURE AND TECHNOLOGY, TOKYO (JP); NISSIN ELECTRIC CO., LTD., KYOTO (JP)

(72) Inventors: TOSHIYUKI SAMESHIMA, TOKYO (JP); YASUNORI ANDO, KYOTO (JP); SYUNJI TAKASE, KYOTO (JP); YOSHITAKA SETOGUCHI, KYOTO (JP)

(73) Assignees: NATIONAL UNIVERSITY CORPORATION TOKYO UNIVERSITY OF AGRICULTURE AND TECHNOLOGY, TOKYO (JP); NISSIN ELECTRIC CO., LTD., KYOTO (JP)

(21) Appl. No.: 14/964,588

(22) Filed: Dec. 10, 2015

(30) Foreign Application Priority Data
Dec. 10, 2014 (JP) 2014-249606

(51) Int. Cl. H01L 31/0687; H01L 31/0224; H01L 31/18; H01L 31/028

(52) U.S. Cl. CPC H01L 31/0687; H01L 31/028; H01L 31/022425; H01L 31/022475; H01L 31/1804; H01L 31/1884

(57) ABSTRACT

A multi-junction solar cell is provided and includes: a first solar cell element, having a first band gap and transmitting a part of incident light; a first conductive film, formed on a back surface of the first solar cell element and having light transmissivity and conductivity; a second solar cell element, having a second band gap smaller than the first band gap; a second conductive film, formed on a front surface of the second solar cell element and having light transmissivity and conductivity; and an adhesion layer, joining surfaces of the first and second conductive films, and having light transmissivity and conductivity. When refractive indexes of the first solar cell element, the first conductive film, the second solar cell element, the second conductive film and the adhesion layer are n₁, n₂, n₃, n₄ and n₅, respectively, relations of n₁>n₂>n₅ and n₃>n₄>n₅ are satisfied.

### CROSS-REFERENCE TO RELATED APPLICATION

This application claims the priority benefit of Japan application serial no. 2014-249606, filed on Dec. 10, 2014. The entirety of the above-mentioned patent application is hereby incorporated by reference herein and made a part of this specification.

### TECHNICAL FIELD

The disclosure relates to a multi-junction solar cell and a method for manufacturing the same, wherein the multi junction solar cell is constituted by joining, with an adhesion layer having light transmissivity and conductivity, at least two solar cell elements containing semiconductors having band gaps different from each other. The multi-junction solar cell having such a configuration may also be called an adhesive multi-junction solar cell.

### DESCRIPTION OF THE BACKGROUND ART

Sunlight has a spectrum over a wide range of energies as shown in FIG. 1.

A solar cell made of a semiconductor absorbs light having an energy equal to or larger than a band gap of the semiconductor so as to generate electricity. For example, crystalline silicon has a band gap of 1.12 eV, and absorbs light having an energy of 1.12 eV or more so as to generate holes and electrons within the crystalline silicon. Under irradiation with a fixed light, an energy difference between the holes and the electrons is determined by the band gap of the semiconductor. Therefore, in the case of crystalline silicon, the energy difference is 1.12 eV regardless of wavelength of incident light.

An open-circuit voltage V_{oc} of the solar cell shown in FIG. 2 is determined by hole electron polarization efficiency in the semiconductor. The open-circuit voltage V_{oc} has a value not exceeding but approximating to the band gap (the numerical value when expressed in unit of eV) of the semiconductor. Thus, when irradiated with short-wavelength light having an energy larger than the band gap, the open-circuit voltage V_{oc} still remains a small value approximating to the band gap, and a loss of incident light energy occurs in the semiconductor.

In order to produce large electromotive force and large electric power with short-wavelength light, a multi junction solar cell formed by superimposing a plurality of semiconductors having different band gaps and different spectral absorption sensitivities has been developed.

For example, a multi-junction solar cell formed by laminating p-n junctions of InGaP, InGaAs and Ge using epitaxial crystal growth techniques, as in the example shown in FIG. 3, has been proposed (see Non-Patent Document 1). Such a multi junction solar cell is capable of absorbing light in a wide range from visible to infrared regions so as to generate electricity, and has high efficiency.

However, the epitaxial crystal growth techniques have a problem that the film forming speed is generally slow, and multi-junction formation takes time. In addition, there is also a problem that, because a large number of different crystals are laminated, the yield is reduced due to occurrence of crystal defects or the like. In addition, there is also a problem that, as it is necessary to alleviate stress between different crystals, application to large-area solar cells is difficult.

On the other hand, as in the example shown in FIG. 4, a technique of superimposing and joining, with a transparent conductive adhesive, a plurality of solar cell elements having different band gaps and previously fabricated as stand-alone solar cells has been proposed (see Patent Document 1 and Non-Patent Document 2). This may also be called an adhesive multi-junction solar cell.

This technique joins completed solar cell elements, and therefore can be expected to have a high yield. In addition, there is an advantage that since a heterogeneous semiconductor crystal growth process is not required, it is possible to manufacture large-area multi-junction solar cells.

### PRIOR ART DOCUMENT

### Patent Document

Patent Document 1: JP 2011-210766

[Non-Patent Documents]

[Non-Patent Document 1] Japanese Journal of Applied Physics, Vol. 43, No. 3, 2004, pp. 882-889, “Evaluation of InGaP/InGaAs/Ge Triple-Junction Solar Cell under Concentrated Light by Simulation Program with Integrated Circuit Emphasis,” K. Nishioka, T. Takamoto, T. Agui, M. Kaneiwa, Y. Uraoka and T. Fuyuki.

[Non-Patent Document 2] T. Sameshima, J. Takenezawa, M. Hasumi, T. Koida, T. Kaneko, M. Karasawa and M. Kondo, “Multi Junction Solar Cells Stacked with Transparent and Conductive Adhesive,” Jpn. J. Appl. Phys. 50 (2011) 052301-1-4.

Although the multi-junction solar cell as shown in FIG. 4 has the advantage as described above, the upper (first) solar cell element becomes a main cause of blockage of light to the lower (second) solar cell element. The same situation also occurs in the multi-junction solar cell as shown in FIG. 3. That is, the upper solar cell element has a large band gap and is thus transparent with respect to long-wavelength light, and the multi-junction solar cell is expected to be well suited for use. However, since the semiconductor generally has a high refractive index, even within a transparent wavelength band with respect to the semiconductor, light is reflected in the vicinity of an interface between the upper and lower solar cell elements, and cannot be smoothly transmitted to the lower solar cell element, which causes a reflection loss.

### SUMMARY

Therefore, the disclosure is to further improve the adhesive multi-junction solar cell as shown in FIG. 4, so as to reduce the reflection loss between the first solar cell element and the second solar cell element, and increase light transmittance.

The multi-junction solar cell according to the disclosure includes: a first solar cell element, containing a semiconductor having a first band gap, generating electricity using an incident light and transmitting a part of the light; a first conductive film, formed on a back surface of the first solar cell element and having light transmissivity and conductivity; a second solar cell element, containing a semiconductor having a second band gap smaller than the first band gap, and generating electricity using an incident light; a second conductive film, formed on a front surface of the second solar cell element and having light transmissivity and conductivity; and an adhesion layer, joining a surface of the first conductive film and a surface of the second conductive film, and having light transmissivity and conductivity, wherein when refractive indexes of the first solar cell element, the first conductive film, the second solar cell element, the second conductive film and the adhesion layer are n₁, n₂, n₃, n₄ and n₅, respectively, the following relations are satisfied:

n₁>n₂>n₅; and

n₃>n₄>n₅.

When a wavelength of light corresponding to the band gap of the first solar cell element is a wavelength of light corresponding to the band gap of the second solar cell element is λ₂, and m is an integer of 0 or greater, a film thickness d₁ of the first conductive film and a film thickness d₂ of the second conductive film may be within the following ranges:

{(1+2m)/4n₂}×{(λ₁+λ₂)/3}≦d₁≦{(1+2m)/4n₂}×{(λ₁+λ₂)/1.5}; and

{(1+2m)/4n₄}×{(λ₁+λ₂)/3}≦d₂≦{(1+2m)/4n₄}×{(λ₁+λ₂)/1.5}.

When the first conductive film has a film thickness of d₁ nm and resistivity of ρ₁ Ωcm, and the second conductive film has a film thickness of d₂ nm and resistivity of ρ₂ Ωcm, the following relations may be satisfied:

1/d₁≧ρ₁≧1×10⁻⁶/d₁; and

1/d₂≧ρ₂≧1×10⁻⁶/d₂.

A method for manufacturing a multi-junction solar cell according to the disclosure is provided, and includes: a first step of fabricating a first solar cell element that contains a semiconductor having a first band gap, generates electricity using an incident light and transmits a part of the light; a second step of forming, on a back surface of the first solar cell element, a first conductive film that has light transmissivity and conductivity by a thin film forming method; a third step of fabricating a second solar cell element that contains a semiconductor having a second band gap smaller than the first band gap, and generates electricity using an incident light; a fourth step of forming, on a front surface of the second solar cell element, a second conductive film that has light transmissivity and conductivity by a thin film forming method; and a fifth step of joining, with an adhesive that has light transmissivity and conductivity, the first solar cell element on which the first conductive film is formed and the second solar cell element on which the second conductive film is formed by using a surface of the first conductive film and a surface of the second conductive film as joined surfaces, wherein when refractive indexes of the first solar cell element, the first conductive film, the second solar cell element, the second conductive film and the adhesive are n₁, n₂, n₃, n₄ and n₅, respectively, the following relations are satisfied:

n₁>n₂>n₅; and

n₃>n₄>n₅.

### BRIEF DESCRIPTION OF THE DRAWINGS

FIG. 1 shows an example of a spectrum of sunlight.

FIG. 2 shows an example of a current-voltage characteristic of a solar cell.

FIG. 3 is a schematic cross-sectional diagram showing an example of a conventional multi-junction solar cell.

FIG. 4 is a schematic cross-sectional diagram showing another example of a conventional multi-junction solar cell.

FIG. 5 is a schematic cross-sectional diagram showing an embodiment of the multi-junction solar cell according to the disclosure.

FIG. 6 is a schematic cross-sectional diagram showing a more specific example of embodiment of the multi junction solar cell according to the disclosure.

FIGS. 7A and 7B are schematic cross-sectional diagrams showing an example of the steps of the method for manufacturing a multi junction solar cell according to the disclosure.

FIG. 8 shows an example of results obtained by calculating an effect of connection resistance on conversion efficiency in a multi-junction solar cell.

FIGS. 9A to 9C are schematic cross-sectional diagrams showing configurations of Examples 1 and 2 and Comparative Examples 1 and 2 used in an experiment.

FIG. 10 shows an example of results obtained by measuring a light transmittance spectrum in Example 1 and Comparative Examples 1 and 2.

FIG. 11 shows an example of results obtained by measuring a light transmittance spectrum in Example 2 and Comparative Examples 1 and 2.

FIG. 12 shows an example of a relationship between film thickness of an IGZO film and effective transmittance of light in the configuration shown in FIG. 9A.

FIG. 13 is a schematic cross-sectional diagram for explaining, in terms of the first (or the second) conductive film, the principle of a case where light reflectance of an interface between upper and lower surfaces of the conductive film is reduced.

FIG. 14 is a schematic diagram showing an example of a spectrum of sunlight.

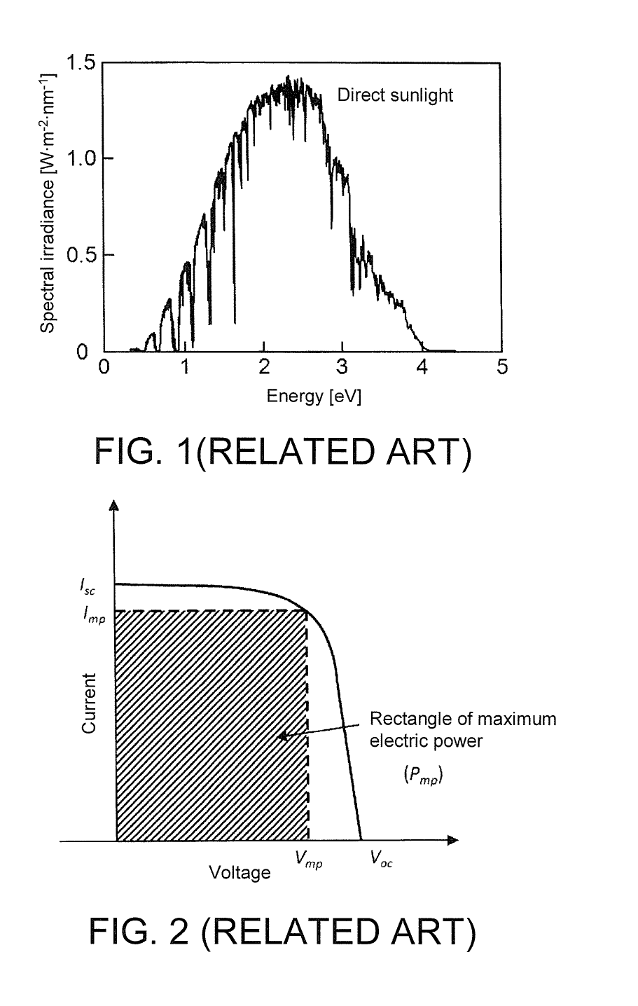

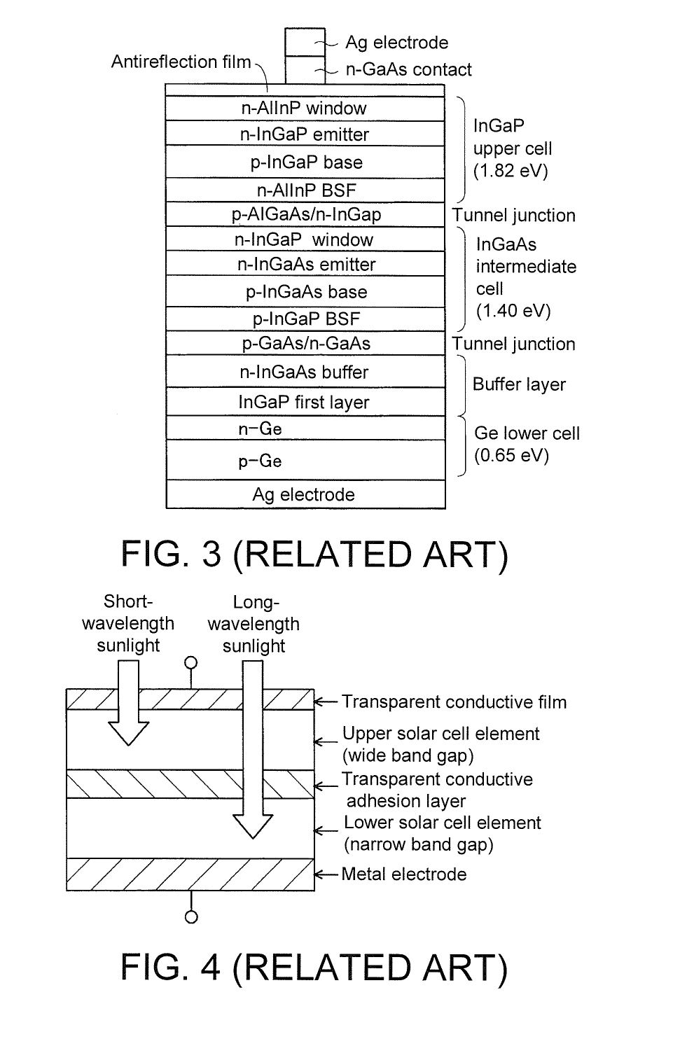

### DESCRIPTION OF THE EMBODIMENTS

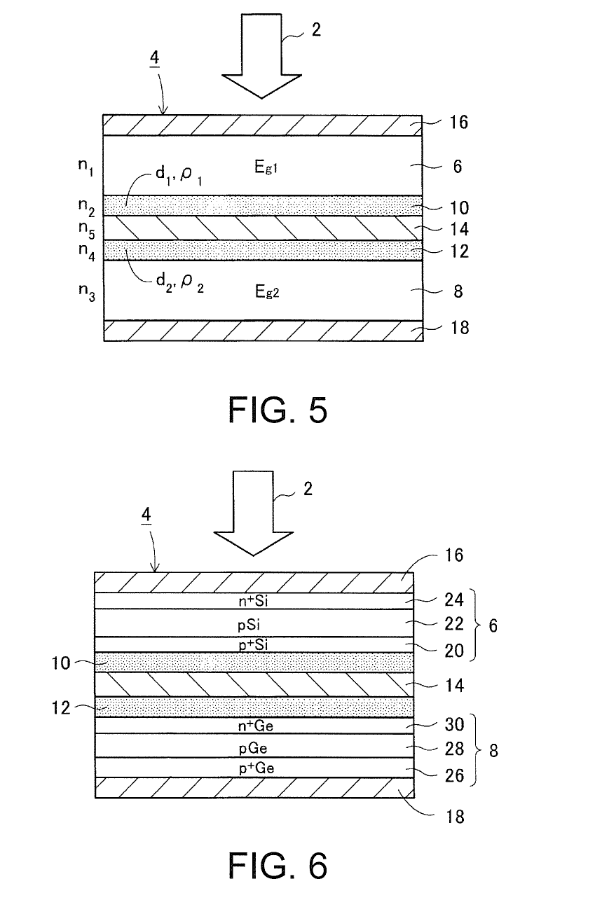

FIG. 5 shows an embodiment of the multi-junction solar cell according to the disclosure. The multi junction solar cell 4 includes two solar cell elements 6 and 8, which is an embodiment of a so-called two junction case. The two junction case is also referred to as a multi-junction solar cell in this application. However, the disclosure is not limited to the two-junction case.

The multi junction solar cell 4 includes: the first solar cell element 6, containing a semiconductor having a first band gap E_{g1}, generating electricity using an incident light 2 (specifically, sunlight) and transmitting a part of the light 2; a first conductive film 10, formed on a back surface of the first solar cell element 6 and having light transmissivity and conductivity; the second solar cell element 8, containing a semiconductor having a second band gap E_{g2} smaller than the first band gap E_{g1} (i.e., E_{g1}>E_{g2}), and generating electricity using an incident light; a second conductive film 12, formed on a front surface of the second solar cell element 8 and having light transmissivity and conductivity; and an adhesion layer 14, joining a surface of the first conductive film 10 and a surface of the second conductive film 12, and having light transmissivity and conductivity. Having light transmissivity is also referred to as “being transparent” in the field of physics.

Moreover, when refractive indexes of the first solar cell element 6, the first conductive film 10, the second solar cell element 8, the second conductive film 12 and the adhesion layer 14 are n₁, n₂, n₃, n₄ and n₅, respectively, relations of the following expression are satisfied.

n₁>n₂>n₅; and

n₃>n₄>n₅ [Expression 1]

In this embodiment, since there is no other solar cell element below the second solar cell element 8, the second solar cell element 8 does not necessarily have to transmit a part of incident light. If another solar cell element is provided below the second solar cell element 8, it is satisfactory if the solar cell element 8 transmits a part of incident light.

Each of the solar cell elements 6 and 8 is, e.g., a silicon-based solar cell, such as a well-known monocrystalline silicon solar cell, polycrystalline silicon solar cell, thin film silicon solar cell, or hybrid solar cell formed by laminating amorphous silicon and monocrystalline silicon, etc.; a germanium-based solar cell using germanium instead of silicon, a compound-based solar cell using such as InGaAs or GaAs, an organic solar cell, or other solar cell, and is not limited to specific configurations. The band gaps of the semiconductors are, e.g., 1.11 eV for Si, 0.67 eV for Ge, 1.43 eV for GaAs, and 3.4 eV for GaN.

A more specific example is shown in FIG. 6. In this example, the solar cell element 6 has a configuration in which a p-type silicon 22 is formed on a p⁺-type silicon 20, and an n⁺-type silicon 24 is formed on the p-type silicon 22. The band gap E_{g1} of the solar cell element 6 is 1.11 eV. The solar cell element 8 has a configuration in which a p-type germanium 28 is formed on a p⁺-type germanium 26, and an n⁺-type germanium 30 is formed on the p-type germanium 28. The band gap E_{g2} of the solar cell element 8 is 0.67 eV. Accordingly, the aforementioned relation E_{g1}>E_{g2} is satisfied.

Referring again to FIG. 5, each of the conductive films 10 and 12 is, e.g., an oxide semiconductor film such as an IGZO (In—Ga—Zn—O/indium-gallium-zinc-oxygen) film, an ITZO (In—Sn—Zn—O/indium-tin-zinc-oxygen) film, or a ZnO (zinc oxide) film, etc., but may also be other conductive film. The oxide semiconductor film as described above has both high light transmissivity and conductivity, and also has good ability to control resistivity. Accordingly, it is suitable for enhancing the conversion efficiency of the multi junction solar cell 4. For example, by heating each of the conductive films 10 and 12 at a required temperature for a required period of time, the resistivity of each of the conductive films 10 and 12 can be relatively easily controlled.

Among the oxide semiconductor films, the IGZO film may be more preferable since it has good ability to control the resistivity.

The film thickness of each of the conductive films 10 and 12 is, e.g., about 200 nm to 500 nm, but is not limited to this range.

Each of the conductive films 10 and 12 may be, e.g., a single layer film having a single refractive index, or may be formed of a plurality of layers of films having different refractive indexes. When the conductive film is formed of a plurality of layers of films, a refractive index (e.g., a Fresnel combined effective refractive index) obtained by combining the refractive indexes of each layer of film may be used as the refractive indexes n₂ and n₄. The same also applies to the refractive indexes n₁ and n₃ in a case where each of the solar cell elements 6 and 8 is formed of a plurality of layers of semiconductors. The Fresnel combined effective refractive index is simply defined as follows. That is, when light is incident on an interface between substances having different refractive indexes, a part of the light is reflected while another part is transmitted (refracted). This behavior is described by a Fresnel equation, and a combined effective refractive index of a plurality of layers of films calculated using the Fresnel equation is the Fresnel combined effective refractive index.

The adhesion layer 14 is, e.g., formed by dispersing ITO (indium tin oxide) particles in a transparent adhesive, but may also have other configurations. Since the ITO particles have both high light transmissivity and conductivity, they are suitable for enhancing the conversion efficiency of the multi-junction solar cell 4.

More specific examples of the transparent adhesive that composes the adhesion layer 14 are, for example, an epoxy resin-based adhesive or a cellulose adhesive. The ITO particles, e.g., have a diameter of 20 μm to 25 μm, and may be dispersed in the above adhesive in an amount of, e.g., 5 wt % to 6 wt %.

A front surface electrode 16 and a back surface electrode 18 may be provided on front and back surfaces respectively of the multi junction solar cell 4, if necessary. The front surface electrode 16 on the side where the light 2 is incident is, e.g., a transparent conductive film such as an ITO film or the like. The back surface electrode 18 may be, e.g., a transparent conductive film such as an ITO film or the like, or may be a non-transparent metal electrode.

In the multi-junction solar cell 4, since the band gap E_{g1} of the first solar cell element 6 is larger than the band gap E_{g2} of the second solar cell element 8 (i.e., E_{g1}>E_{g2}) as mentioned above, the first solar cell element 6 on the upper side absorbs light within the incident light 2 that has an energy larger than the band gap E_{g1}, i.e., light having a wavelength shorter than that equivalent to the band gap E_{g1} so as to generate electricity, and transmits light having a wavelength longer than that equivalent to the band gap E_{g1}. The solar cell element 8 on the lower side absorbs the light transmitted from the solar cell element 6 and having the longer wavelength so as to generate electricity. In this way, since both the solar cell elements 6 and 8 are capable of generating electricity, the conversion efficiency is high.

As well known, energy E [eV] and wavelength λ [nm] of light have a relation of the following expression.

E=1240/λ [Expression 2]

The multi junction solar cell 4 is configured by joining the first solar cell element 6 and the second solar cell element 8 using the adhesion layer 14. Therefore, the manufacture thereof is simple, and a high yield can be expected. In addition, since a heterogeneous semiconductor crystal growth process is not required, it is possible to manufacture large-area multi-junction solar cells.

Moreover, since the multi-junction solar cell 4 includes the first conductive film 10, the second conductive film 12 and the adhesion layer 14, and satisfies the relations of refractive index shown in Expression 1 above, light reflectance between the first solar cell element 6 and the adhesion layer 14 and between the adhesion layer 14 and the second solar cell element 8 is reduced. Accordingly, a reflection loss between the first solar cell element 6 and the second solar cell element 8 is reduced and the light transmittance can be increased. As a result, since the light can efficiently reach the second solar cell element 8, the conversion efficiency of the multi-junction solar cell 4 can be enhanced.

In order to further reduce the light reflectance between the solar cell element 6 and the adhesion layer 14 and between the adhesion layer 14 and the solar cell element 8, the refractive indexes n₁, n₂, n₃, n₄ and n₅ more preferably satisfy relations of the following expression.

n₂=(n₁×n₅)^{0.5}; and

n₄=(n₃×n₅)^{0.5} [Expression 3]

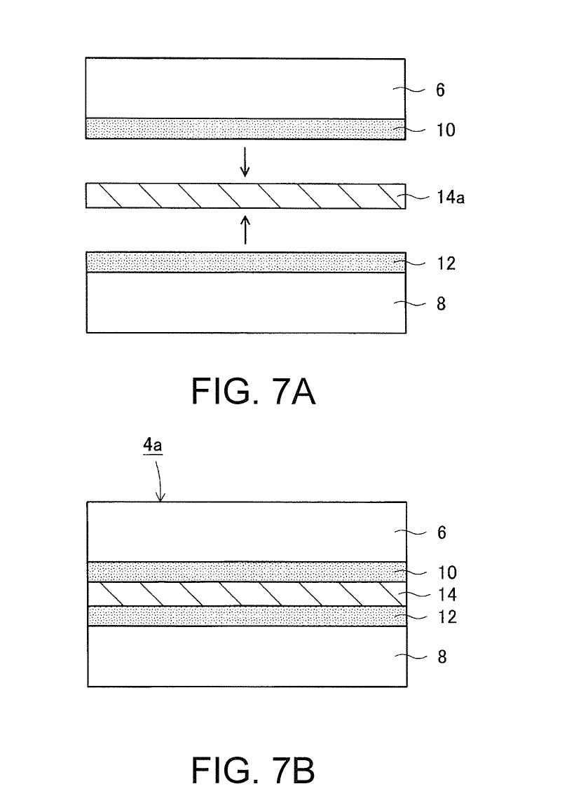

An example of a method for manufacturing the multi-junction solar cell 4 as described above is explained with reference to FIG. 7A and FIG. 7B.

The method for manufacturing a multi-junction solar cell according to the disclosure includes: a first step of fabricating a first solar cell element 6 as described above; a second step of forming a first conductive film 10 as described above on a back surface of the solar cell element 6 by a thin film forming method; a third step of fabricating a second solar cell element 8 as described above; and a fourth step of forming a second conductive film 12 as described above on a front surface of the solar cell element 8 by a thin film forming method.

The thin film forming method is, e.g., a vacuum deposition method, a plasma CVD method, or a plasma sputtering method, etc.

The first step and the second step may be separately performed or may be successively performed. Similarly, the third step and the fourth step may be separately performed or may be successively performed.

This manufacturing method further includes a fifth step (see FIG. 7A) of joining, with an adhesive 14a having light transmissivity and conductivity, the solar cell element 6 on which the conductive film 10 is formed and the solar cell element 8 on which the conductive film 12 is formed by using a surface of the conductive film 10 and a surface of the conductive film 12 as joined surfaces. The adhesive 14a serves as the aforementioned adhesion layer 14. Examples of the adhesive 14a are the same as those of the adhesion layer 14.

According to the above, a multi-junction solar cell 4a shown in FIG. 7B can be manufactured. If the front surface electrode 16 and the back surface electrode 18 are formed as needed, the multi junction solar cell 4 shown in FIG. 5 and so on can be obtained.

When the adhesion is performed using the adhesive 14a, a required pressure (e.g., about 5×10⁵ Pa) may be applied. Heating at a required temperature may also be performed if necessary.

Also, in this manufacturing method, when refractive indexes of the first solar cell element 6, the first conductive film 10, the second solar cell element 8, the second conductive film 12 and the adhesive 14a are n₁, n₂, n₃, n₄ and n₅, respectively, the aforementioned relations of Expression 1 are satisfied.

According to this manufacturing method, the first solar cell element 6 on which the conductive film 10 is formed and the second solar cell element 8 on which the conductive film 12 is formed are respectively fabricated in advance, and then are joined (stuck together) using the adhesive 14a. Thus, compared to a method of manufacturing a multi junction solar cell by sequentially laminating a large number of solar cell elements by the thin film forming method, the manufacture is simpler and the yield is higher. That is, the multi-junction solar cell 4 having the features as described above can be easily manufactured.

Next, preferred film thicknesses of the conductive films 10 and 12 are explained. FIG. 13 is a schematic cross-sectional diagram for explaining, in terms of the first (or the second) conductive film 10 (or 12), the principle of a case where light reflectance of an interface between upper and lower surfaces of the conductive film is reduced. Moreover, in FIG. 13, the reason that the light 2 is incident in a slightly inclined manner is simply to easily illustrate reflected lights 2a and 2b in the drawing.

Firstly, regarding the first conductive film 10, within the light 2 passing through the first solar cell element 6 to enter the conductive film 10, an optical path difference D between the reflected light 2a on the interface of the upper surface of the conductive film 10 and the reflected light 2b on the interface of the lower surface of the conductive film 10 is represented by the following expression, wherein d₁ is the film thickness of the conductive film 10 and n₂ is the refractive index of the conductive film 10.

D=2n₂d₁ [Expression 4]

When the optical path difference D is (½+m)λ, the reflected lights 2a and 2b cancel each other, and thus the reflectance is minimized. That is, the transmittance is maximized. m is an integer of 0 or greater (i.e., m=0, 1, 2, . . . ). Accordingly, the film thickness d₁ that maximizes the transmittance is represented by the following expression, wherein λ, is the wavelength explained hereinafter.

d₁={(1+2m)/4n₂}λ [Expression 5]

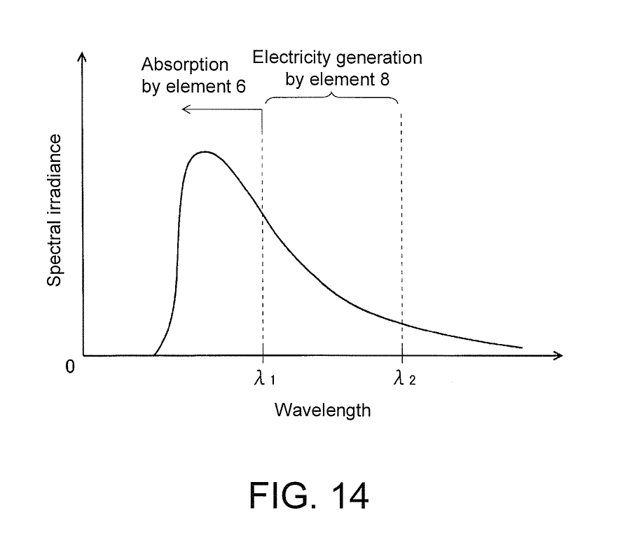

The way of obtaining the wavelength λ in the above expression is explained. Herein, description is given in terms of electricity generation in the second (lower) solar cell element 8. Thus, when a wavelength corresponding to the band gap of the solar cell element 6 is λ₁, and a wavelength corresponding to the band gap of the solar cell element 8 is λ₂, with reference also to FIG. 14, light within the incident light 2 of a wavelength not greater than λ₁ is absorbed by the solar cell element 6 and utilized for electricity generation. As a result, a wavelength that can be utilized for electricity generation by the solar cell element 8, i.e., the wavelength λ in Expression 5, falls within a range of the following expression.

λ₁<λ≦λ₂ [Expression 6]

In the above, the wavelength λ is particularly preferably an average value and is represented by the following expression.

λ=(λ₁+λ₂)/2 [Expression 7]

However, the preferred wavelength λ is not only limited to the average value, but may be within a certain range including the average value. As shown in FIG. 14, considering that spectral irradiance of sunlight is higher on the shorter wavelength side between the wavelengths λ₁ and λ₂, the range of the wavelength side shorter than the average value may be widened. Thus, the wavelength λ is preferably within a range represented by the following expression.

(λ₁+λ₂)/3≦λ≦(λ₁+λ₂)/1.5 [Expression 8]

Accordingly, from Expression 8 and Expression 5 above, a preferred range of the film thickness d₁ of the conductive film 10 is represented by the following expression, wherein when m=0, the film thickness d₁ is minimized.

{(1+2m)/4n₂}×{(λ₁+λ₂)/3}≦d₁≦{(1+2m)/4n₂}×{(λ₁+λ₂)/1.5} [Expression 9]

Regarding the second conductive film 12, similarly to the above, when its film thickness is d₂, and its refractive index is n₄, a preferred range of the film thickness d₂ of the conductive film 12 is represented by the following expression, wherein when m=0, the film thickness d₂ is minimized.

{(1+2m)/4n₄}×{(λ₁+λ₂)/3}≦d₂≦{(1+2m)/4n₄}×{(λ₁+80 ₂)/1.5} [Expression 10]

By respectively setting the film thicknesses d₁ and d₂ of the conductive films 10 and 12 within the ranges represented by Expression 9 and Expression 10, the light reflectance of the interface between the upper and lower surfaces of each of the conductive films 10 and 12 can be reduced. Therefore, the light transmittance is increased and the light can efficiently reach the second solar cell element 8. As a result, the conversion efficiency of the multi junction solar cell 4 can be further enhanced.

Next, preferred resistivities of the conductive films 10 and 12 are explained.

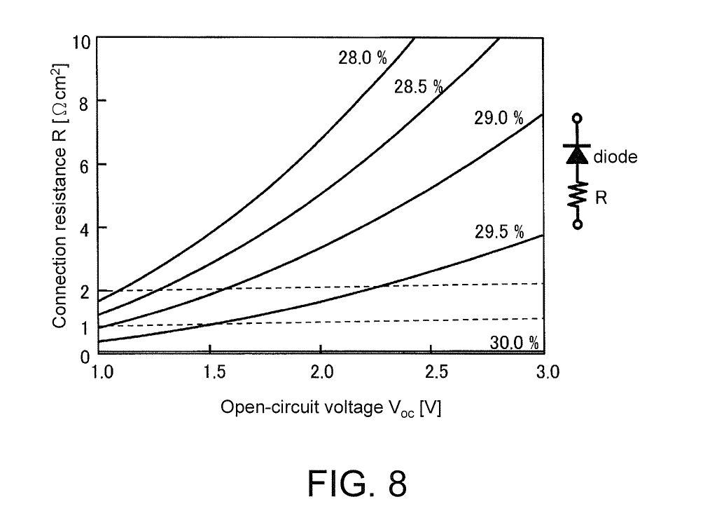

The multi-junction solar cell 4 must cause a current to flow longitudinally. In order to do so, it is necessary that the resistivities of the conductive films 10 and 12 be very small values. This is explained with reference to the example in FIG. 8.

FIG. 8 shows an example of results obtained by calculating an effect of connection resistance on conversion efficiency in a multi-junction solar cell by simulating the multi junction solar cell using a PN diode and a series resistance R shown on the right side of the drawing. As shown in the drawing, when a connection resistance R is present in a solar cell originally having conversion efficiency of 30%, in order to control reduction in the conversion efficiency at an open-circuit voltage V_{oc} of 1.5 V within 0.5%, it is necessary that the connection resistance R be a low resistance of 1 Ωcm² or less. The connection resistance R is a surface resistance; and when the film thickness is d and the resistivity is ρ, there is a relation of R=ρd.

From this, when the first conductive film 10 has a film thickness of d₁ nm and resistivity of ρ₁ Ωcm, and the second conductive film 12 has a film thickness of d₂ nm and resistivity of ρ₂ Ωcm, it is preferred that relations of the following expression be satisfied.

1/d₁≧ρ₁; and

1/d₂≧ρ₂ [Expression 11]

However, when resistance is small and conductivity is large, free carrier absorption of light occurs in the conductive film. It is particularly pronounced in the infrared region. Accordingly, in order to reduce loss of light caused by the free carrier absorption in a wavelength (e.g., 1850 nm for Ge) equivalent to the band gap of the semiconductor used in the lower solar cell element 8 to 1% or less, the resistivities ρ₁ and ρ₂ of the conductive films 10 and 12 preferably satisfy relations of the following expression.

ρ₁≧1×10⁻⁶/d₁; and

ρ₂≧1×10⁻⁶/d₂ [Expression 12]

Accordingly, by integrating Expressions 11 and 12, the resistivities ρ₁ and ρ₂ of the conductive films 10 and 12 are preferably within ranges represented by the following expression.

1/d₁≧ρ₁≧1×10⁻⁶/d₁; and

1/d₂≧ρ₂≧1×10⁻⁶/d₂ [Expression 13]

Thereby, the connection resistance between the solar cell elements 6 and 8 is reduced, and the reduction in conversion efficiency of the multi-junction solar cell 4 resulting from the connection resistance can be minimized. Moreover, since the loss of light caused by free carrier absorption in the first conductive film 10 and the second conductive film 12 can be reduced, the light can efficiently reach the second solar cell element 8. Due to these two reasons, the conversion efficiency of the multi junction solar cell 4 can be further enhanced.

As stated above, the disclosure is not limited to the two-junction case having two solar cell elements 6 and 8, but is also applicable to cases having three or more solar cell elements, so-called three (or more) junction cases. In the three (or more)-junction cases, for example, (a) another one or more layers of solar cell elements may be provided above the first solar cell element 6 (and below the front surface electrode 16). Or, (b) another one or more layers of solar cell elements may be provided below the second solar cell element 8 (and above the back surface electrode 18). Or, (a) and (b) may be combined. In teems of two adjacent solar cell elements among the solar cell elements, the same configuration as that described above with respect to the first solar cell element 6, the first conductive film 10, the second solar cell element 8, the second conductive film 12 and the adhesion layer 14 may be adopted.

### [Experiment Results]

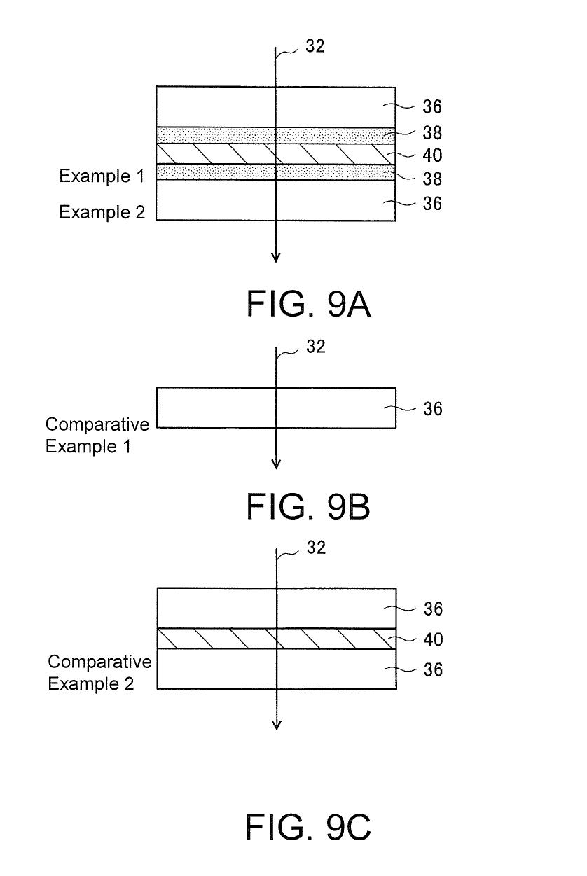

Next, an example of results of an experiment to measure a light transmittance spectrum using the samples and so on for simulating the multi-junction solar cell 4 is explained. The configurations of Examples 1 and 2 and Comparative Examples 1 and 2 used in this experiment are shown in FIG. 9A to FIG. 9C.

A monocrystalline silicon substrate 36 having a thickness of 500 μm and a refractive index of 3.5 was used as a semiconductor substrate, and on its surface, an IGZO film 38 having a refractive index of 1.85 was formed by a sputtering method. A sample (for Example 1) in which the IGZO film 38 has a film thickness of 500 nm and a sample (for Example 2) in which the IGZO film 38 has a film thickness of 200 nm were produced, two for each kind of sample. Further, in order to set the resistivity of the IGZO film 38 within the range shown in Expression 13, a 1-hour heat treatment was applied to each sample at 350° C., so as to set the resistivity of the IGZO film 38 to 0.03 Ωcm.

As shown in FIG. 9A, the two samples each having the IGZO film 38 having a film thickness of 500 nm formed therein were joined using an adhesive 40 being transparent and conductive and having a refractive index of 1.3, by using the IGZO films 38 as joined surfaces, wherein the adhesive 40 was formed by dispersing ITO particles having a diameter of 20 μm in a transparent epoxy resin-based adhesive in an amount of 6 wt %. This sample is referred to as Example 1. In the same way, the two samples each having the IGZO film 38 having a film thickness of 200 nm formed on the surface of the monocrystalline silicon substrate 36 were joined using the same adhesive 40 as above. This sample is referred to as Example 2. Examples 1 and 2 simulated the multi-junction solar cell 4, and both satisfy the relations of refractive index shown in Expression 1.

In addition, for comparison, as shown in FIG. 9B, a sample including only the same monocrystalline silicon substrate 36 as above was also used. This is referred to as Comparative Example 1. Further, as shown in FIG. 9C, two monocrystalline silicon substrates 36 being the same as above with no IGZO film 38 formed thereon were joined using the same adhesive 40 as above. This is referred to as Comparative Example 2. Comparative Example 2 simulated the conventional multi-junction solar cell shown in FIG. 4.

As shown in FIG. 9A to FIG. 9C, light 32 was transmitted through Examples 1 and 2 and Comparative Examples 1 and 2, and transmittance spectra thereof were measured. In this measurement, a calculation program composed of Fresnel light interference and free carrier absorption effects was used.

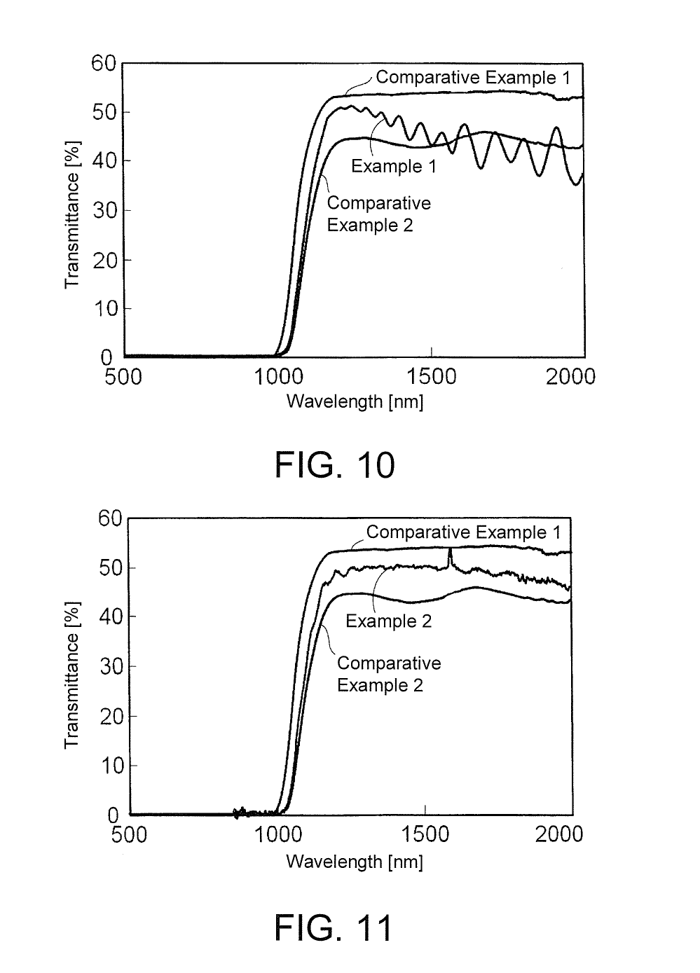

FIG. 10 shows an example of results obtained by measuring the light transmittance spectrum in Example 1 in which the IGZO film 38 has a film thickness of 500 nm and Comparative Examples 1 and 2. In Example 1, due to formation of the IGZO film 38, at wavelengths ranging from 1100 nm to 1600 nm, a larger increase in the transmittance was observed than in Comparative Example 2, and an effect of reducing reflection loss by foundation of the IGZO film 38 can be confirmed. A value obtained by integrating the transmittance of Comparative Example 1 in the wavelength range from 1100 nm to 1600 nm was 1, and effective transmittance of Example 1 was 0.88.

FIG. 11 shows an example of results obtained by measuring the light transmittance spectrum in Example 2 in which the IGZO film 38 has a film thickness of 200 nm and Comparative Examples 1 and 2. In Example 2, due to formation of the IGZO film 38, at wavelengths ranging from 1100 nm to 1600 nm, a larger increase in the transmittance was observed than in Comparative Example 2. Moreover, the increase was more uniform than in Example 1. The effect of reducing reflection loss by formation of the IGZO film 38 can be confirmed. Effective transmittance of Example 2 was 0.92.

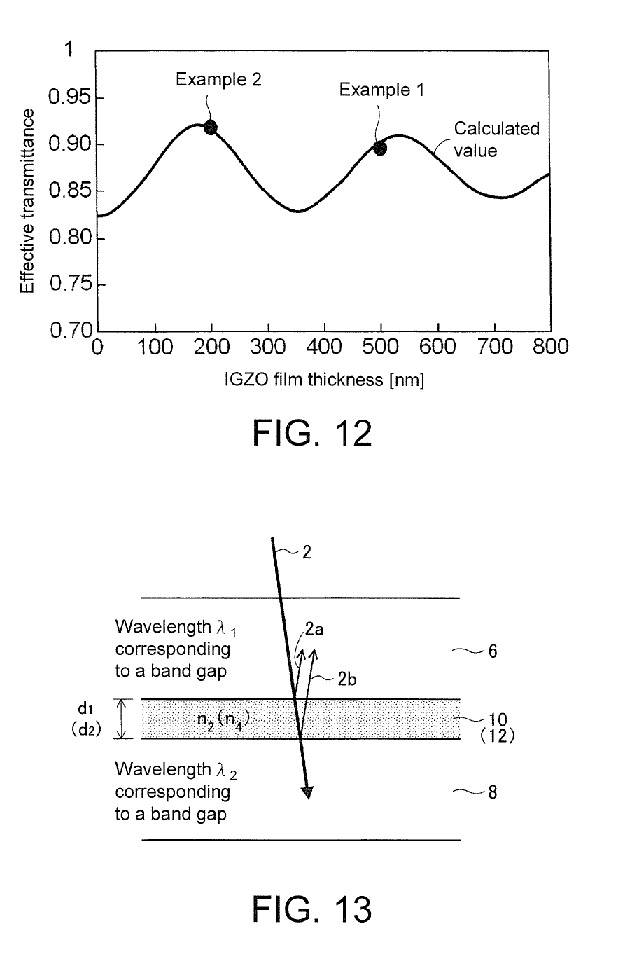

FIG. 12 shows an example of a relationship between film thickness of the IGZO film 38 and effective transmittance of light in the configuration shown in FIG. 9A. Calculated value in FIG. 12 indicates a result obtained by calculating the effective transmittance by changing the film thickness of the IGZO film 38 according to calculations, wherein Examples 1 and 2 indicate the results of Examples 1 and 2 in the aforementioned experiment.

As shown as the calculated value, when the IGZO film thickness is changed, an optical path difference between the reflected lights on the interface between the upper and lower surfaces of the film is changed and a condition of interference of the two reflected lights is periodically changed. Therefore, there was a periodical change in the effective transmittance according to the film thickness of the IGZO film 38. The maximum effective transmittance was calculated to be 0.925 at the film thickness of the IGZO film 38 of 175 nm. In addition, it is clear that Examples 1 and 2 are highly consistent with the calculated value.

1. A multi-junction solar cell, comprising:
a first solar cell element, containing a semiconductor having a first band gap, generating electricity using an incident light and transmitting a part of the light;
a first conductive film, formed on a back surface of the first solar cell element and having light transmissivity and conductivity;
a second solar cell element, containing a semiconductor having a second band gap smaller than the first band gap, and generating electricity using an incident light;
a second conductive film, formed on a front surface of the second solar cell element and having light transmissivity and conductivity; and
an adhesion layer, joining a surface of the first conductive film and a surface of the second conductive film, and having light transmissivity and conductivity,
wherein when refractive indexes of the first solar cell element, the first conductive film, the second solar cell element, the second conductive film and the adhesion layer are n₁, n₂, n₃, n₄ and n₅, respectively, the following relations are satisfied:
n₁>n₂>n₅; and
n₃>n₄>n₅.

2. The multi-junction solar cell of claim 1, wherein when a wavelength of light corresponding to the band gap of the first solar cell element is λ₁, a wavelength of light corresponding to the band gap of the second solar cell element is λ₂, and m is an integer of 0 or greater, a film thickness d₁ of the first conductive film and a film thickness d₂ of the second conductive film are within the following ranges:
{(1+2m)/4n₂}×{(λ₁+λ₂)/3}≦d₁≦{(1+2m)/4n₂}×{(λ₁+λ₂)/1.5}; and
{(1+2m)/4n₄}×{(λ₁+λ₂)/3}≦d₂≦{(1+2m)/4n₄}×{(λ₁+λ₂)/1.5}.

3. The multi-junction solar cell of claim 1, wherein
when the first conductive film has a film thickness of d₁ nm and resistivity of ρ₁ Ωcm, and the second conductive film has a film thickness of d₂ nm and resistivity of ρ₂ Ωcm, the following relations are satisfied:
1/d₁≧ρ₁≧1×10⁻⁶/d₁; and
1/d₂≧ρ₁≧1×10⁻⁶/d₂.

4. The multi-junction solar cell of claim 1, wherein
the first conductive film and the second conductive film are oxide semiconductor films.

5. The multi-junction solar cell of claim 1, wherein
the adhesion layer is obtained by dispersing Indium Tin Oxide particles in a transparent adhesive.

6. A method for manufacturing a multi junction solar cell, comprising:
a first step of fabricating a first solar cell element that contains a semiconductor having a first band gap, generates electricity using an incident light and transmits a part of the light;
a second step of forming, on a back surface of the first solar cell element, a first conductive film that has light transmissivity and conductivity by a thin film forming method;
a third step of fabricating a second solar cell element that contains a semiconductor having a second band gap smaller than the first band gap, and generates electricity using an incident light;
a fourth step of forming, on a front surface of the second solar cell element, a second conductive film that has light transmissivity and conductivity by a thin film forming method; and
a fifth step of joining, with an adhesive that has light transmissivity and conductivity, the first solar cell element on which the first conductive film is formed and the second solar cell element on which the second conductive film is formed by using a surface of the first conductive film and a surface of the second conductive film as joined surfaces, wherein
when refractive indexes of the first solar cell element, the first conductive film, the second solar cell element, the second conductive film and the adhesive are n₁, n₂, n₃, n₄ and n₅, respectively, the following relations are satisfied:
n₁>n₂>n₅; and
n₃>n₄>n₅.
